(19) United States
(12) Patent Application Publication
(10) Pub. No.: US 2008/0013648 A1
(43) Pub. Date: Jan. 17, 2008

(54) DECODING SYSTEM AND METHOD FOR DECIDING A COMPENSATED SIGNAL

(75) Inventors: Ming-Chou Yen, Hsin-Chu (TW); Kun-Ying Tsai, Hsin-Chu (TW); Ling-I Ho, Hsin-Chu (TW); Chun-Wang Wei, Hsin-Chu (TW); Jui-Tai Ko, Hsin-Chu (TW)

Correspondence Address: PATTERSON, THUENTE, SKAAR & CHRISTENSEN, P.A., 4800 IDS CENTER, 80 SOUTH 8TH STREET, MINNEAPOLIS, MN, 55402-2100, US

(73) Assignee: RDC SEMICONDUCTOR CO., LTD., Hsin-Chu (TW)

(21) Appl. No.: 11/458,023

(22) Filed: Jul. 17, 2006

(51) Int. Cl. H04L 27/06; H03H 7/30

(52) U.S. Cl. 375/340; 375/233

(57) ABSTRACT

Decoding systems and methods for deciding a compensated signal are provided. The decoding system comprises a slicer, a compensator, and a selector. The slicer is used for generating a pre-decision symbol. The compensator is used for determining a predetermined range of the compensated signal. The selector is used for deciding the compensated signal in response to the pre-decision symbol, the predetermined range and a set of previous symbols. The predetermined range is to limit the calculation range of the compensated signal so that the required hardware is reduced.

### CROSS-REFERENCES TO RELATED APPLICATIONS

Not applicable

### BACKGROUND OF THE INVENTION

1. Field of the Invention

The present invention relates to decoding systems and methods for deciding a compensated signal; specifically relates to decoding systems and methods for deciding a compensated signal in response to a convoluted signal.

2. Descriptions of the Related Art

Due to the rapid development of multimedia technologies, most Internet services support multimedia data. However, the size of multimedia data is usually huge. When a large number of multimedia data are transmitted at the same time, such a huge amount of multimedia transmissions cause a lot of burdens on the traditional 100 Mbps (Mega bits per second) network. Thus, gigabit Ethernet is developed to solve the problem.

FIG. 1 illustrates a schematic architecture of the gigabit Ethernet, in which there are two transceivers 10 and 11 for transmitting and receiving signals. The two transceivers 10 and 11 use four twisted cables 12, Category 5 cable, as a transmission channel. Since it is a dispersive transmission channel, there exists Inter-Symbol Interference (ISI) which would degrade the transmission quality. In order to preserve good transmission quality, the transceivers 10 and 11 usually adopt five-level Pulse Amplitude Modulate (PAM-5) and Trellis Coded Modulation (TCM) to reduce the degradation and to increase coding gains without extra bandwidth.

Several decoding architectures are designed based on the aforementioned encoding and modulation techniques. For example, FIG. 2 illustrates a conventional decoding system that comprises a Decision Feedback Equalizer (DFE) 21 and a Viterbi decoder 22. The DFE 21 receives a transmitted signal 201 and generates an equalized signal 203 after equalizing the transmitted signal 201. The Viterbi decoder 22 generates a decoded signal 205 according to the equalized signal 203. The advantage of the decoding system is its simple architecture. However, it causes a drawback of having a poor coding gain. FIG. 3 illustrates another decoding architecture of the prior art, which introduces several DFEs 31 to feed back results generated by the Viterbi decoder 22 as a reference to obtain a symbol of the next time. In addition, it also comprises a feed forward equalizer 23. The coding gain of the decoding system shown in FIG. 3 is much higher, whereas it has drawbacks of having a complicated architecture and hard achievement of pipelining.

In U.S. Pat. No. 6,959,038, an approach that improves the aforementioned architectures is disclosed. However, when the length of a channel memory is increased, the complexity of the hardware adapted for the approach increases exponentially. Once the length reaches a critical level, the decoding complexity is unacceptable. A decoding system, involving a Viterbi algorithm, which is implemented according to the approach also causes high complexity of the hardware and makes pipelining hard to be realized.

In order to reduce the hardware complexity due to convolution coding and in order to achieve pipelining, a decoding system as illustrated in FIG. 4 is disclosed in U.S. Pat. No. 6,690,754. The following description is based on one of four twisted cables. A received signal 401 is processed by a slicer 41 and a DFE circuit 42. Then, the adder 43 sums up a processed signal 403 and the received signal 401. A summed signal 405 is transmitted to a Reduced State Sequence Estimation (RSSE) circuit 44 for decoding.

The RSSE circuit 44 is used to process main components of ISI. The DFE circuit 42 is used to deal with sub-components of ISI. The high complexity of the hardware resulted from the approach disclosed in U.S. Pat. No. 6,959,038 seems to be solved by the disclosure of U.S. Pat. No. 6,690,754. Nevertheless, the RSSE circuit 44 does not make the situation better when a lot of the mixed main components of ISI exist in the summed signal 405.

Consequently, a solution that can decode signals efficiently and reduce the complexity of hardware implementation is highly demanded in the industrial field.

### SUMMARY OF THE INVENTION

An object of this invention is to provide a decoding system for deciding a compensated signal. The decoding system comprises a slicer, a compensator, and a selector. The slicer is configured to generate a pre-decision symbol. The compensator is configured to determine a predetermined range of the compensated signal. The selector is configured to decide the compensated signal in response to the pre-decision symbol, the predetermined range and a set of previous symbols.

Another object of this invention is to provide a decoding method for deciding a compensated signal. The decoding method comprises the steps of generating a pre-decision symbol; determining a predetermined range of the compensated signal; and deciding the compensated signal in response to the pre-decision symbol, the predetermined range, and a set of previous symbols.

The predetermined range is to limit the calculation range of the compensated signal so that the required hardware is reduced. That is, the present invention reduces the complexity of the hardware by only calculating fewer symbols.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 illustrates a schematic architecture of gigabit Ethernet;

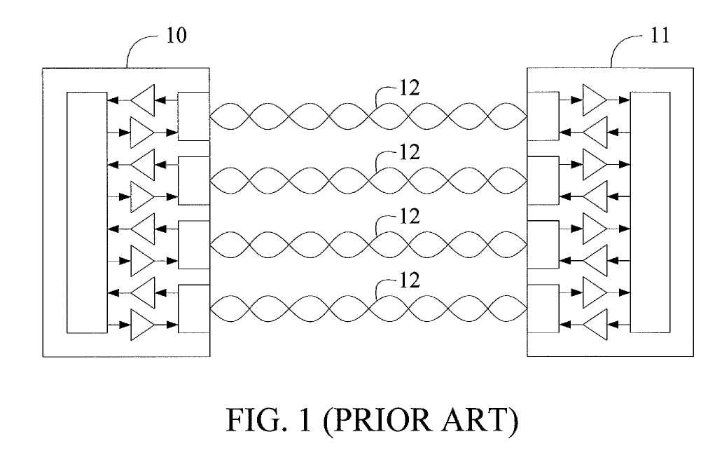

FIG. 2 illustrates a decoding system of the prior art;

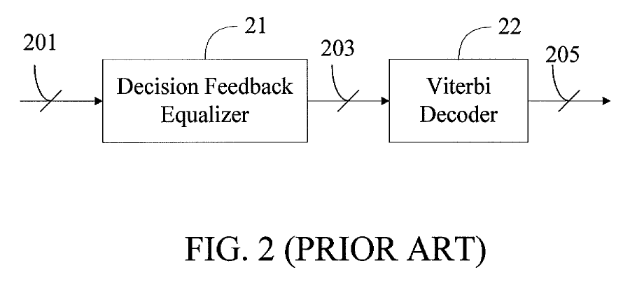

FIG. 3 illustrates another decoding system of the prior art;

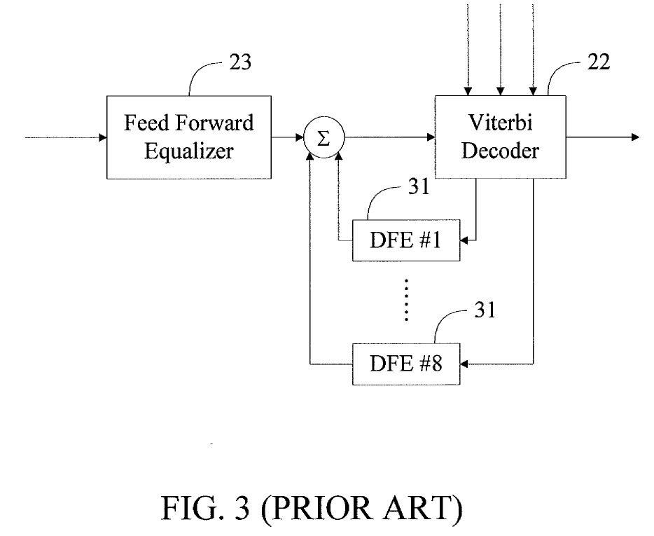

FIG. 4 illustrates a decoding system disclosed in U.S. Pat. No. 6,690,754;

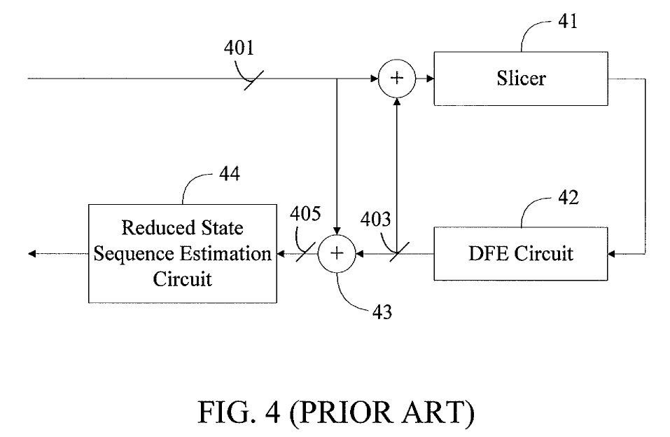

FIG. 5A illustrates a first embodiment of the present invention;

FIG. 5B illustrates a compensator of the first embodiment; and

FIG. 6 illustrates a second embodiment of the present invention.

### DESCRIPTION OF THE PREFERRED EMBODIMENT

In this specification, the term “in response to” is defined as “replying to” or “reacting to.” For example, “in response to a signal” means “replying to a signal” or “reacting to a signal” without necessity of direct signal reception. The term “according to” or “based on” has a definition similar to that of the term “in response to.”

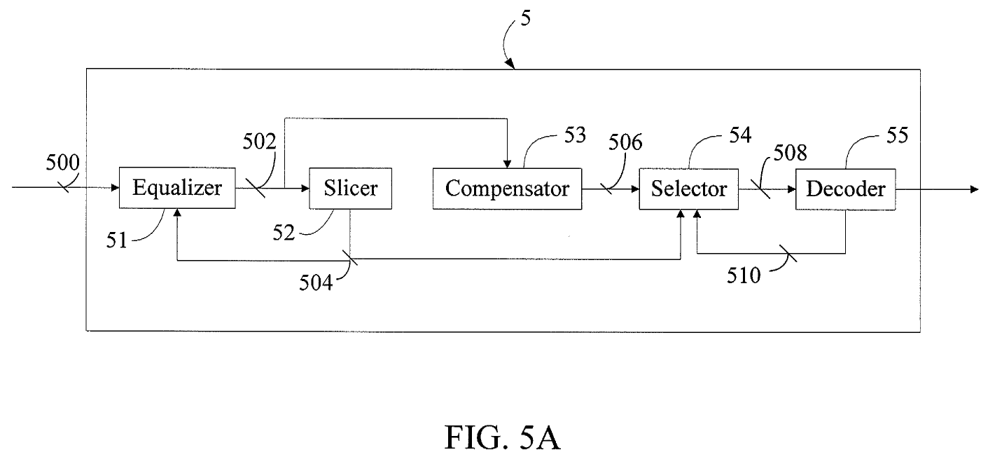

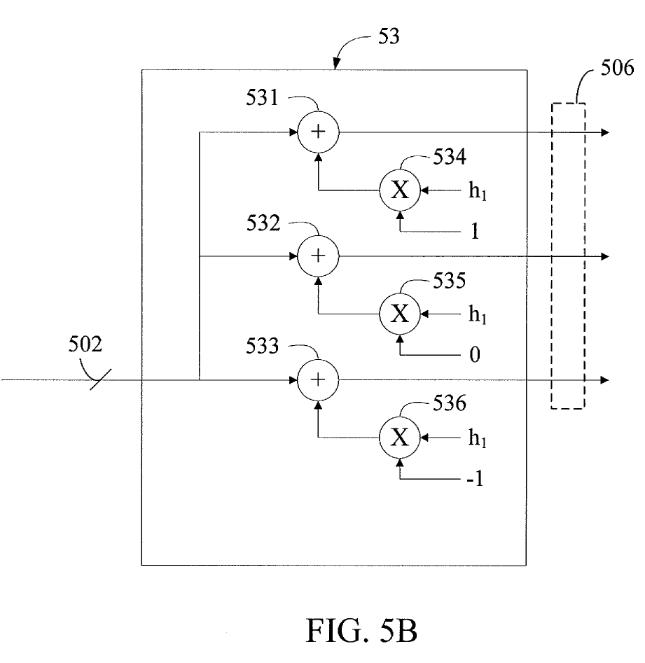

FIG. 5A illustrates a first embodiment of the present invention, in which a decoding system 5 adapted for a communication system is depicted. The communication system further comprises an encoding system (not shown) for encoding and transmitting a signal 500. The decoding system 5 is configured to decide a compensated signal when receiving the signal 500. The compensated signal is then used to generate a decoded signal. The decoding system 5 can be applied to most networks, such as gigabit Ethernet, as a receiver, wherein the signal 500 is transmitted under the standard of PAM-5 and TCM. In addition, the encoding system and the decoding system 5 are connected through four twisted cables (not shown), which are category 5 cables.

People skilled in the coding field should be familiar with PAM-5 and TCM, so the details of PAM-5 and TCM are not recited in the specification. In the following description, the first embodiment is recited simply for one of four twisted cables.

The decoding system 5 illustrated in FIG. 5A comprises an equalizer 51, a slicer 52, a compensator 53, a selector 54, and a decoder 55. The equalizer 51 equalizes the received signal 500 to remove ISI and generates an equalized signal 502. Since the equalizer 51 reduces the influence of ISI, the outcome of the decoding system 5 can be derived more accurately. The slicer 52, a soft slicer or a hard slicer, generates a pre-decision symbol 504 in time k-i in response to the equalized signal 502. The pre-decision symbol 504 is a pre-estimated symbol based on the equalized signal 502. The compensator 53 determines a predetermined range 506 of the compensated signal in time k in response the equalized signal 502. Then, the selector 54 decides the compensated signal 508 in time k in response to the pre-decision symbol 504, the predetermined range 506, and a set of previous symbols 510 in time k-1, wherein the set of previous symbols 510 comprises at least one symbol which is determined in a previous time by the decoder 55. The number of the symbols in the set of previous symbols 510 may be determined according to practical needs.

In the first embodiment, the decoder 55 is a Viterbi decoder. The present invention does not intend to limit the type of the decoder 55. In other words, any decoder that can decode a convoluted signal may be used herein. The decoder 55 decodes the compensated signal 508 if the difference between the set of previous symbols 510 and the pre-decision symbol 504 is within the predetermined range 506. On the other hand, if the difference between the set of previous symbols 510 and the pre-decision symbol 504 is out of the predetermined range 506, the decoder 55 ignores a current symbol from a branch. The branch is in a decoding path adapted for TCM and the decoder 55 decodes the compensated signal based on the decoding path.

More particularly, since the communication system is operated under the standard of PAM-5 and TCM, the possible symbols at each state of the decoding system 5 is +2, +1, 0, −1, and −2. It means that the correct path in each state is decided based on the branch metric of the possible symbols carried by the equalized signal 502. The predetermined range 506 is configured to narrow the number of the possible symbols from five to, for example, three in order to reduce hardware complexity of the decoding system 5.

Due to ISI, the received signal 500 has a response comprising components h0, h1, h2, . . . , and hn. The equalizer 51 removes the distortion and generates the equalized signal 502. The slicer 52 generates the pre-decision symbol 504 that has a high probability to be the symbol the encoding system transmits. The pre-decision symbol 504 is then transmitted to the selector 54 and fed back to the equalizer 51 for the purpose of improving the precision of equalization. The compensator 53 also receives the equalized signal 502. For the sake of simplification, assume that the decoder 55 decodes the symbol in time k-1 is +1. The probability that the symbol 504 in time k-1 is −1 or −2 is quite low and it almost does not occur. Therefore, in the first embodiment, if the difference between the set of previous symbols 510 and the pre-decision symbol 504 is 0, −1, or +1, i.e. plus, minus one and zero in terms of the pre-decision symbol 504, the selector 54 may generate the correct compensated signal 508 and the decoder 55 decodes the compensated signal 508 to obtain the symbol in time k.

In the first embodiment, if the difference between the set of previous symbols 510 and the pre-decision symbol 504 is not within the predetermined range 506, that means the received signal 500 has too much noise to be decoded correctly. The selector 54 outputs the compensated signal 508 with a predetermined value so that the decoder 55 can realize that the symbol from the branch should be ignored in time k.

The detail circuitry of the compensator 53 is illustrated in FIG. 5B. In this embodiment, the compensator 53 comprises three adders 531, 532, 533 and three multipliers 534, 535, 536. The three multipliers 534, 535, 536 multiply three reference signals which are 1, 0, and −1 with the sub-component h1 of the response, respectively. The three reference signals represent plus, minus one and zero, respectively. The three adders 531, 532, 533 sum up the multiplication results and the equalized signal 502 to determine the predetermined range 506. Therefore, the equalized signal 502 and the three reference signals together define the predetermined range 506. The selector 54 decides the compensated signal 508 by comparing the set of previous symbols 510 and the pre-decision symbol 504 with the reference to the reference signals. Please note that the number of the reference signals is smaller than the number of the acceptable symbols under the standard of TCM; therefore the complexity of the hardware of the first embodiment is reduced.

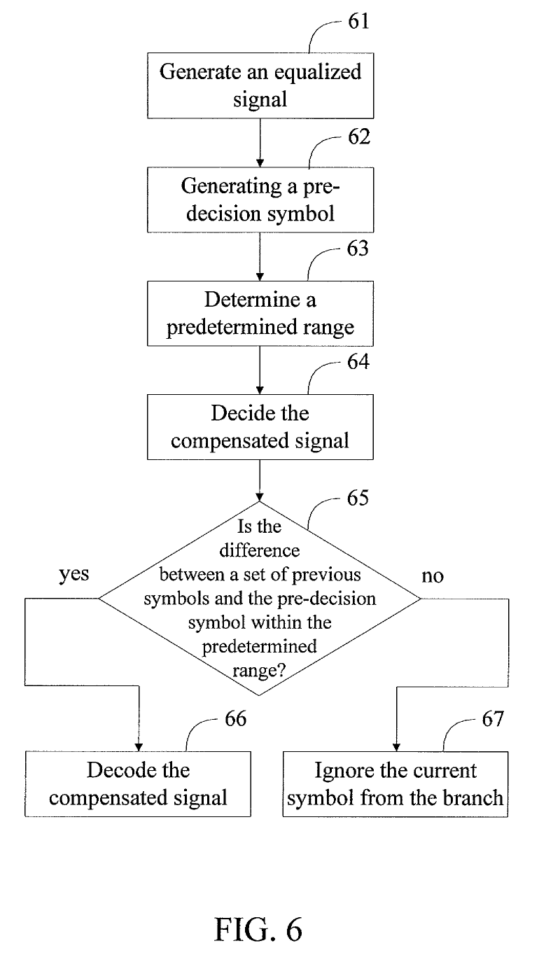

FIG. 6 illustrates a second embodiment of the present invention, in which a method for deciding a compensated signal is depicted. The second embodiment is adapted for a decoding system like the first embodiment. First, step 61 is executed to generate an equalized signal in response to a received signal. Step 62 is executed to generate a pre-decision symbol in response to the equalized signal. Step 63 is then executed to determine a predetermined range of the compensated signal in response to the equalized signal. Step 64 is then executed to decide the compensated signal in response to the pre-decision symbol, the predetermined range, and a set of previous symbols, wherein the predetermined range is plus one, minus one, and zero in terms of the pre-decision symbol. Step 65 is then executed to determine if the difference between a set of previous symbols and the pre-decision symbol is within the predetermined range. If yes, step 66 is executed to decode the compensated signal with reference to a branch. The branch is in a decoding path and the compensated signal is decoded based on the decoding path. If no, step 67 is executed to ignore the current symbol from the branch. In addition to the steps shown in FIG. 6, the second embodiment may perform all of the operations or functions recited in the first embodiment. Those skilled in the art can straightforwardly realize how the second embodiment performs these operations and functions based on the above descriptions of the first embodiment. Therefore, the descriptions for these operations and functions are redundant and not repeated herein.

The present invention provides a predetermined range of the compensated signal to simplify the calculation amount of obtaining the symbol in each state. In other words, the hardware complexity is reduced. The cost is saved thereby.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A decoding system for deciding a compensated signal, comprising:
a slicer for generating a pre-decision symbol;
a compensator for determining a predetermined range of the compensated signal; and
a selector for deciding the compensated signal in response to the pre-decision symbol, the predetermined range and a set of previous symbols.

2. The decoding system of claim 1, further comprising an equalizer for generating an equalized signal in response to a received signal, wherein the slicer generates the pre-decision symbol in response to the equalized signal.

3. The decoding system of claim 2, wherein the compensator determines the predetermined range in response to the equalized signal.

4. The decoding system of claim 2, further comprising a decoder, wherein if the difference between the set of previous symbols and the pre-decision symbol is within the predetermined range, the decoder decodes the compensated signal in response to the set of previous symbols.

5. The decoding system of claim 4, wherein the decoder is a Viterbi decoder.

6. The decoding system of claim 4, wherein the predetermined range is plus, minus one and zero in terms of the pre-decision symbol.

7. The decoding system of claim 2, wherein the compensator generates M reference signals, and the equalized signal and the M reference signals define the predetermined range.

8. The decoding system of claim 7, wherein the selector compares the set of previous symbols and the pre-decision symbol by reference to the M reference signals to decide the compensated signal.

9. The decoding system of claim 8, the compensated signal being determined by following a decoding path, wherein each state of the decoding path has N acceptable symbols and M is smaller than N.

10. The decoding system of claim 9, wherein the decoding path is Trellis decoded.

11. The decoding system of claim 2, further comprising a decoder, wherein if the difference between the set of previous symbols and the pre-decision symbol is out of the predetermined range, the decoder ignores a current symbol from a branch, wherein the branch is in a decoding path, and the decoder decodes the compensated signal based on the decoding path.

12. The decoding system of claim 1, further comprising a decoder for generating the set of previous symbols.

13. A decoding method for deciding a compensated signal, comprising the steps of:
generating a pre-decision symbol;
determining a predetermined range of the compensated signal; and
deciding the compensated signal in response to the pre-decision symbol, the predetermined range, and a set of previous symbols.

14. The decoding method of claim 13, further comprising the step of generating an equalized signal in response to a received signal, wherein the step of generating a pre-decision symbol responds to the equalized signal.

15. The decoding method of claim 14, wherein the determining step responds to the equalized signal.

16. The decoding method of claim 14, further comprising the steps of:
determining if the difference between the set of previous symbols and the pre-decision symbol is within the predetermined range; and
decoding the compensated signal in response to the set of previous symbols if yes.

17. The decoding method of claim 16, wherein the predetermined range is plus, minus one and zero in terms of the pre-decision symbol.

18. The decoding method of claim 14, wherein the determining step comprises the step of generating M reference signals, and the equalized signal and the M reference signals define the predetermined range.

19. The decoding method of claim 18, wherein the deciding step comprises the step of comparing the set of previous symbols and the pre-decision symbol by reference to the M reference signals.

20. The decoding method of claim 19, the compensated signal being determined by following a decoding path, wherein each state of the decoding path has N acceptable symbols and M is smaller than N.

21. The decoding method of claim 14, further comprising the steps of:
determining if the difference between the set of previous symbols and the pre-decision symbol is within the predetermined range; and
ignoring a current symbol from a branch if no;
wherein the branch is in a decoding path, and the compensated signal is further processed based on the decoding path.

22. The decoding method of claim 13, further comprising the step of generating the set of previous symbols.
